(19) United States
(12) Patent Application Publication
(10) Pub. No.: US 2008/0054415 A1
(43) Pub. Date: Mar. 6, 2008

(54) N-CHANNEL FIELD EFFECT TRANSISTOR HAVING A CONTACT ETCH STOP LAYER IN COMBINATION WITH AN INTERLAYER DIELECTRIC SUB-LAYER HAVING THE SAME TYPE OF INTRINSIC STRESS

(76) Inventors: Kai Frohberg, Niederau (DE); Hartmut Ruelke, Dresden (DE); Sandra Bau, Dresden (DE)

Correspondence Address: J. Mike Amerson;Williams, Morgan & Amerson, P.C., Suite 1100, 10333 Richmond, Houston, TX, 77042, US

(21) Appl. No.: 11/692,594

(22) Filed: Mar. 28, 2007

(30) Foreign Application Priority Data
Aug. 31, 2006 (DE) 10 2006 040 762.8

(51) Int. Cl. H01L 23/58; H01L 21/302

(52) U.S. Cl. 257/642; 438/725; 257/E29.015

(57) ABSTRACT

By forming a tensile silicon dioxide layer on the basis of a sub-atmospheric deposition technique, the strain-inducing mechanism of a tensile contact etch stop layer for N-channel transistors may be significantly improved. Consequently, for otherwise identical stress conditions, the performance of a respective N-channel transistor may be significantly enhanced.

### BACKGROUND OF THE INVENTION

1. Field of the Invention

Generally, the present disclosure relates to the field of integrated circuits, and, more particularly, to the manufacture of N-channel field effect transistors having a strained channel region caused by a stressed contact etch stop layer.

2. Description of the Related Art

Integrated circuits typically comprise a large number of circuit elements on a given chip area according to a specified circuit layout, wherein, in complex circuits, the field effect transistor represents one important device component. Generally, a plurality of process technologies are currently practiced, wherein, for complex circuitry based on field effect transistors, such as microprocessors, storage chips and the like, MOS technology is currently one of the most promising approaches due to the superior characteristics in view of operating speed and/or power consumption and/or cost efficiency. During the fabrication of complex integrated circuits using MOS technology, millions of transistors (in CMOS technology, complementary transistors, i.e., N-channel transistors and P-channel transistors) are formed on a substrate including a crystalline semiconductor layer. A field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region.

The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the majority charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially determines the performance of the MOS transistors. Thus, the reduction of the channel length, and associated therewith the reduction of the channel resistivity, renders the channel length a dominant design criterion for accomplishing an increase in the operating speed of the integrated circuits.

The shrinkage of the transistor dimensions, however, involves a plurality of issues associated therewith that have to be addressed so as to not unduly offset the advantages obtained by steadily decreasing the channel length of MOS transistors. One problem in this respect is the development of enhanced photolithography and etch strategies to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability.

Since the continuous size reduction of the critical dimensions, i.e., the gate length of the transistors, necessitates the adaptation and possibly the new development of process techniques concerning the above-identified complex process steps, it has been proposed to enhance device performance of the transistor elements not only by reducing the transistor dimensions but also by increasing the charge carrier mobility in the channel region for a given channel length. In principle, at least two mechanisms may be used, in combination or separately, to increase the mobility of the charge carriers in the channel region. First, the dopant concentration within the channel region may be reduced, thereby reducing scattering events for the charge carriers and thus increasing the conductivity. However, reducing the dopant concentration in the channel region significantly affects the threshold voltage of the transistor device, while the reduced channel length may even require enhanced dopant concentrations in order to control short channel effects, thereby making a reduction of the dopant concentration a less attractive approach unless other mechanisms are developed to adjust a desired threshold voltage. Second, the lattice structure in the channel region may be modified, for instance by creating tensile or compressive strain therein, which results in a modified mobility for electrons and holes, respectively. For example, creating tensile strain in the channel region of a silicon layer having a standard crystallographic configuration may increase the mobility of electrons, which, in turn, may directly translate into a corresponding increase in the conductivity for N-type transistors. On the other hand, compressive strain in the channel region may increase the mobility of holes, thereby providing the potential for enhancing the performance of P-type transistors. Consequently, it has been proposed to introduce, for instance, a silicon/germanium layer or a silicon/carbon layer in or near the channel region to create tensile or compressive stress. Although the transistor performance may be considerably enhanced by the introduction of strain-creating layers in or below the channel region, significant efforts have to be made to implement the formation of corresponding strain-inducing layers into the conventional and well-approved CMOS technique. For instance, additional epitaxial growth techniques have to be developed and implemented into the process flow to form the germanium- or carbon-containing stress layers at appropriate locations in or below the channel region. Hence, process complexity is significantly increased, thereby also increasing production costs and the potential for a reduction in production yield. Moreover, currently, highly efficient growth techniques for silicon/germanium are available to provide a strained semiconductor material in the drain and source regions of P-channel transistors, whereas presently available growth techniques for silicon/carbon may be less efficient, thereby reducing the efficiency of the strain-inducing mechanism for N-channel transistors.

Therefore, a technique is frequently used that enables the creation of desired stress conditions within the channel region of different transistor elements by modifying the stress characteristics of a contact etch stop layer that is formed above the basic transistor structure in order to form contact openings to the gate and drain and source terminals in an interlayer dielectric material. The effective control of mechanical stress in the channel region, i.e., effective stress engineering, may be accomplished by individually adjusting the internal stress in the contact etch stop layer in order to position a contact etch contact layer having an internal compressive stress above a P-channel transistor while positioning a contact etch stop layer having an internal tensile strain above an N-channel transistor, thereby creating compressive and tensile strain, respectively, in the respective channel regions.

Typically, the contact etch stop layer is formed by plasma enhanced chemical vapor deposition (PECVD) processes above the transistor, i.e., above the gate structure and the drain and source regions, wherein, for instance, silicon nitride may be used due to its high etch selectivity with respect to silicon dioxide, which is a well-established interlayer dielectric material. Furthermore, PECVD silicon nitride may be deposited with a high intrinsic stress, for example, up to 2 Giga Pascal (GPa) or significantly higher of tensile or compressive stress, wherein the type and the magnitude of the intrinsic stress may be efficiently adjusted by selecting appropriate deposition parameters. For example, ion bombardment, deposition pressure, substrate temperature, gas components and the like represent respective parameters that may be used for obtaining the desired intrinsic stress. Since the contact etch stop layer is positioned close to the transistor, the intrinsic stress may be efficiently transferred into the channel region, thereby significantly improving the performance thereof. Moreover, for advanced applications, the strain-inducing contact etch stop layer may be efficiently combined with other strain-inducing mechanisms, such as strained or relaxed semiconductor materials that are incorporated at appropriate transistor areas in order to also create a desired strain in the channel region. Consequently, the stressed contact etch stop layer is a well-established design feature for advanced semiconductor devices, wherein, however, the interaction of the contact etch stop layer with the overlying interlayer dielectric material, i.e., silicon dioxide formed from TEOS on the basis of PECVD, due to the advantageous characteristics with respect to material integrity in the further manufacturing process, may result in a reduced performance gain as expected, in particular for N-channel transistors, which is believed to be caused by the high compressive stress of the PECVD TEOS silicon dioxide.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein is directed to a technique for inducing strain in respective channel regions of transistors on the basis of stressed overlayers, such as dielectric materials used to embed the transistor, wherein especially the mechanism for inducing tensile strain in the respective channel region may be improved by combining the effects of tensile stress of two different materials used in the interlayer dielectric material. For instance, in some illustrative embodiments, silicon nitride with high intrinsic tensile stress may be formed and may be embedded by a silicon dioxide base material also having a tensile stress. Consequently, the overall efficiency of the strain-inducing mechanism may be significantly enhanced for otherwise identical stress conditions.

According to one illustrative embodiment disclosed herein, a method comprises forming a first overlayer having a first type of intrinsic stress above an N-channel transistor. Furthermore, an interlayer dielectric material is formed on the basis of silicon dioxide on the first overlayer, wherein the interlayer dielectric material comprises at least a layer portion having the first type of intrinsic stress. Furthermore, a contact opening for connecting to the N-channel transistor is formed in the interlayer dielectric material.

According to another illustrative embodiment disclosed herein, a method comprises forming a first silicon nitride layer having a tensile stress above a first transistor. Thereafter, a first silicon dioxide layer is formed on the first silicon nitride layer, wherein the first silicon dioxide layer has a tensile stress. Additionally, a second silicon dioxide layer is formed above the first silicon dioxide layer.

According to yet another illustrative embodiment disclosed herein, a semiconductor device comprises a first transistor and a first stress layer formed above the first transistor, wherein the first stress layer has a tensile stress. Furthermore, a first dielectric layer of an interlayer dielectric material is formed on the first stress layer and has a tensile stress with respect to the first stress layer. Moreover, a second dielectric layer of the interlayer dielectric material is formed above the first dielectric layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a transistor element receiving a stressed contact etch stop layer and a subsequent stressed layer of an interlayer dielectric material according to illustrative embodiments disclosed herein;

FIG. 1c schematically illustrates a cross-sectional view for forming a first portion of an interlayer dielectric material in a non-conformal manner so as to increase a desired horizontal stress component according to illustrative embodiments disclosed herein;

FIG. 1d schematically illustrates a transistor element receiving a contact etch stop layer in a highly non-conformal manner in order to increase the horizontal stress component thereof according to still further illustrative embodiments;

FIGS. 2a-2d schematically illustrate cross-sectional views of a semiconductor device comprising an N-channel transistor and a P-channel transistor, wherein the overall stress transfer mechanism may be adapted to device-specific requirements so as to obtain a non-symmetrical stress-inducing mechanism for the P-channel transistor and the N-channel transistor according to further illustrative embodiments disclosed herein; and

FIGS. 2e-2f schematically illustrate cross-sectional views of the semiconductor device having two different types of transistor elements, wherein a corresponding tensile stress of an interlayer dielectric material is selectively modified according to further illustrative embodiments disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to a technique for providing a strain-inducing mechanism on the basis of stressed overlayers, wherein the efficiency of a tensile stress source may be effectively enhanced by appropriately combining an interlayer dielectric material with a dielectric layer formed close to the respective transistor element, such as a contact etch stop layer, as is typically used for patterning the interlayer dielectric material for receiving respective contact openings. For instance, for standard crystallographic conditions, i.e., for a silicon-based semiconductor material having a (100) surface orientation with respective channel regions oriented along the <110> direction, the mobility of electrons may be significantly enhanced by providing a tensile strain along the channel length direction, which may be accomplished by respective layers positioned close to the transistor element and having a high tensile stress. For this purpose, typically the contact etch stop layer usually formed from silicon nitride is provided with a high tensile stress above N-channel transistors in order to enhance transistor performance. According to the present disclosure, the efficiency of the stressed contact etch stop layer or any other layer formed close to the transistor may be significantly enhanced by providing an appropriate interlayer dielectric material with a high tensile stress, at least at a portion that is in contact with the lower-lying contact etch stop layer, thereby significantly reducing any stress-relaxing effects of an overlying portion of the interlayer dielectric material, which is conventionally provided in the form of a PECVD silicon dioxide, which has superior characteristics with respect to the deposition behavior and the material integrity during the further processing of the semiconductor device. For instance, silicon dioxide formed by PECVD on the basis of TEOS (tetraethyl-ortho-silicate) and oxygen provides relatively high mechanical stability at temperatures below 600° C. at high deposition rates, thereby contributing to a high production throughput. Moreover, the corresponding silicon dioxide exhibits a high resistance against the incorporation of moisture, which may be advantageous in view of the further processing of the device, for instance with respect to performing chemical mechanical polishing (CMP) processes and the like. However, PECVD silicon dioxide formed from TEOS may, despite the various advantageous characteristics, create a respective compressive stress with respect to a deposition surface, thereby resulting in sophisticated applications in a significant stress relaxation with respect to transistor devices requiring a high tensile stress in the vicinity of the channel region. Consequently, the present disclosure contemplates a process technique in which the advantages of a highly stable interlayer dielectric material may be maintained, while nevertheless the stress-reducing effect thereof may be significantly reduced by providing a portion of the interlayer dielectric material in the form of an appropriately stressed material.

For this purpose, in some illustrative embodiments, a silicon dioxide material may be formed on the basis of a thermal chemical vapor deposition (CVD) process using TEOS as a precursor material, wherein the respective deposition process may provide excellent gap-filling capabilities, wherein a high degree of conformality or, if required, a substantially “flow-like” fill behavior may be achieved, depending on the process parameters selected. Typically, the respective thermal deposition process may be performed at significantly higher pressures compared to the plasma enhanced deposition technique, for instance in the range of 200-760 Torr and therefore the process is frequently denoted as “sub-atmospheric” CVD (SACVD). The corresponding silicon dioxide may have significantly different characteristics, in particular in respect to its stress behavior, wherein the silicon dioxide layer formed by SACVD may readily absorb water, resulting in an alteration of the intrinsic stress of the corresponding silicon dioxide layer. Typically, the silicon dioxide layer formed from TEOS on the basis of a thermal CVD process exhibits a moderately high tensile stress upon deposition, wherein any incorporation of water may, however, significantly reduce the tensile stress. According to the subject matter disclosed herein, the respective silicon dioxide materials may be effectively embedded into the remaining highly stable silicon dioxide formed on the basis of the plasma enhanced deposition technique, thereby “conserving” the tensile stress in the lower-lying portion of the interlayer dielectric material. Consequently, compared to conventional devices, a significant performance gain may be obtained for transistor elements requiring a high tensile strain in the respective channel regions. Furthermore, in some illustrative embodiments, the characteristics of the silicon dioxide may be selectively modified so as to reduce the respective tensile stress when a corresponding interaction with the lower-lying transistor elements may not be desirable. For instance, for the above-specified standard crystallographic conditions, the compressive stress in the respective channel region may significantly enhance the hole mobility, wherein a stress relaxation of overlying compressively stressed contact etch stop layers may reduce the performance gain of P-channel transistors. In this case, the effect of the tensile stress of the layer may be reduced by appropriately selected structural means, such as a difference in surface topography, or by any other modification processes, or even by selectively removing the layer portion having the tensile stress. Consequently, the strain engineering of highly scaled CMOS devices may be enhanced, at least for one type of transistors, while not unduly negatively affecting the other type of transistor elements.

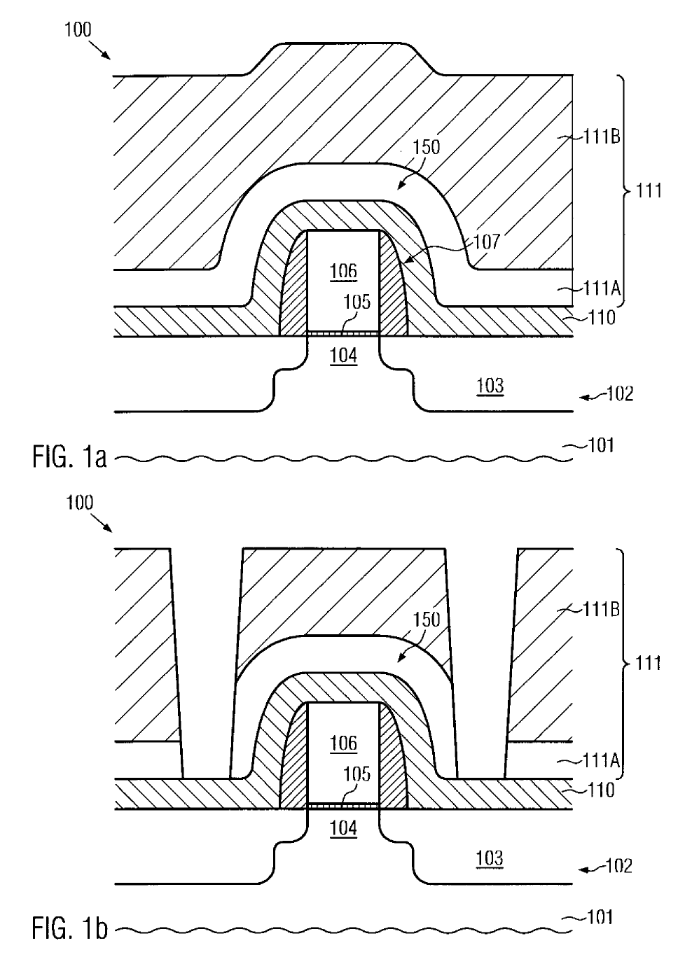

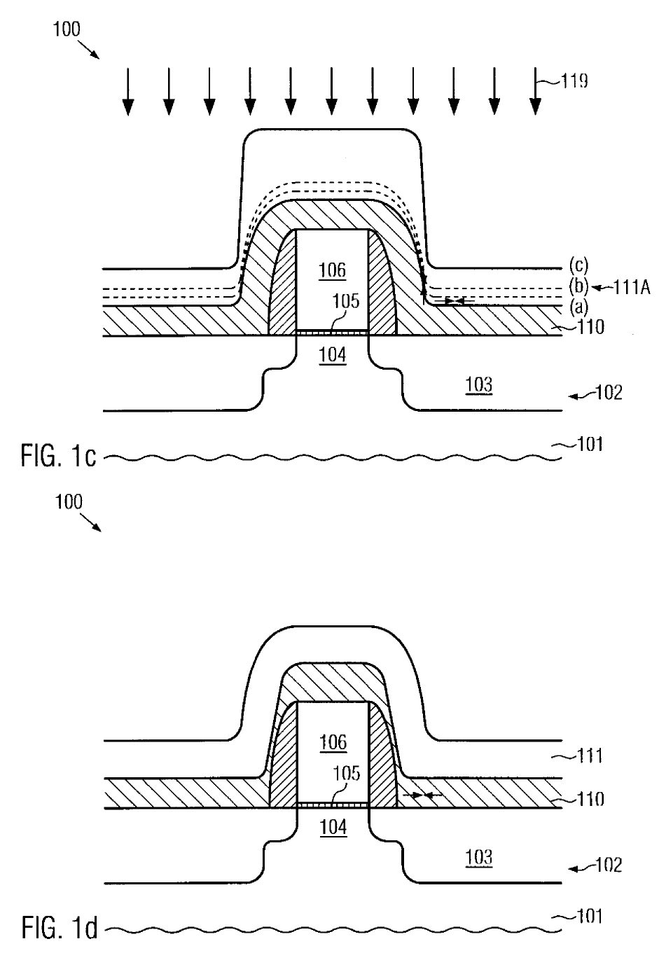

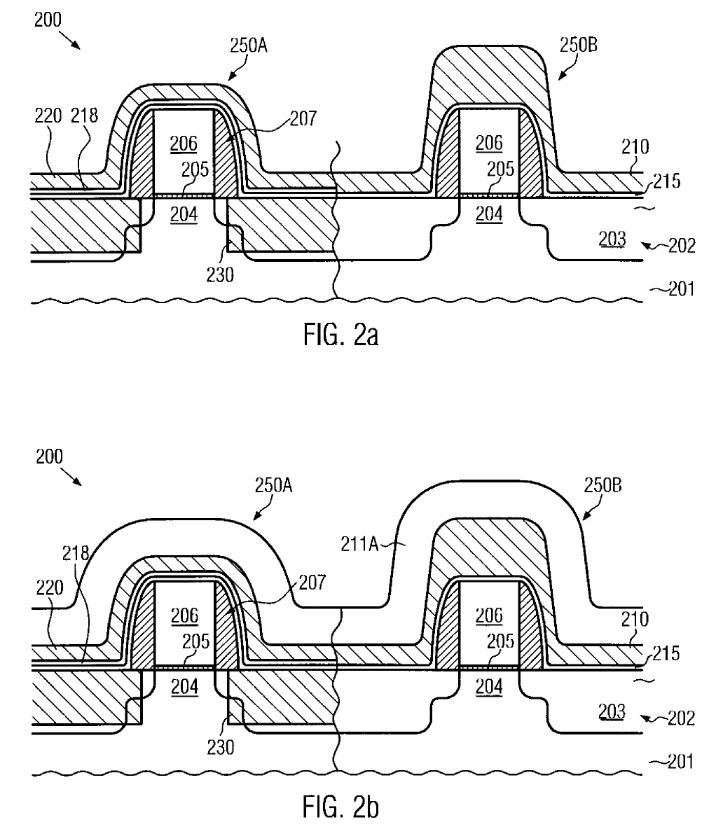

FIG. 1a schematically shows a cross-sectional view of a semiconductor device 100 comprising a transistor 150, which, in one illustrative embodiment, represents an N-channel transistor. In other illustrative embodiments, the transistor 150 may represent any transistor element requiring a high tensile stress provided by any overlying layers embedding the transistor 150. The device 100 may comprise a substrate 101, which may represent any appropriate carrier material, such as a semiconductor bulk substrate, a silicon-on-insulator (SOI) type substrate and the like. For example, the substrate 101 may represent a bulk silicon substrate having formed thereon an appropriate semiconductor layer 102, such as a silicon-based material, the characteristics of which, with respect to charge carrier mobility, may be locally adjusted by inducing a corresponding strain in specified portions of the semiconductor layer 102. In other cases, the substrate 101 may have formed thereon a buried insulating layer (not shown) on which may be formed the semiconductor layer 102 so as to provide an SOI architecture. Furthermore, the semiconductor layer 102 may comprise respective isolation structures (not shown), such as shallow trench isolations and the like, in order to define respective active regions, in which an appropriate vertical and lateral dopant profile is to be established in order to obtain the required locally varying conductive behavior. Thus, one or more transistor elements, such as the transistor 150, may be formed in and on a corresponding active area bordered by a respective isolation structure, wherein, for convenience, a single transistor element is shown in FIG. 1a.

In this manufacturing stage, the transistor 150 may comprise a channel region 104, i.e., an appropriately doped area bordered by respective drain and source regions 103, which are typically inversely doped with respect to the channel region 104. For instance, if the transistor 150 is to represent an N-channel transistor, the drain and source regions 103 may be heavily doped with an N-type dopant, while the channel region 104 may have formed therein a significantly reduced concentration of P-type dopant materials. A gate electrode 106 is formed above the channel region 104 and is separated therefrom by a gate insulation layer 105, which may be comprised of any appropriate material, such as silicon dioxide, silicon nitride, silicon oxynitride and the like. As previously explained, the gate electrode 106 is provided for controlling the conductivity of the channel region 104, wherein, for given transistor dimensions, i.e., a given channel length, which substantially represents the horizontal extension of the channel region 104, and for a given transistor width, i.e., the direction of the transistor 150 perpendicular to the drawing plane of FIG. 1a, the drive current capability is significantly affected by the charge carrier mobility of the majority charge carriers accumulating in the channel region 104, i.e., in the case of an N-channel transistor, the electrons. In sophisticated applications, the length of the channel region 104 may be approximately 90 nm and significantly less, or even 50 nm and less for semiconductor devices of the 90 nm technology node.

Furthermore, a sidewall spacer structure 107 may be formed on sidewalls of the gate electrode 106, wherein the configuration of the spacer structure 107 may depend on the device and process requirements. It should be appreciated that the spacer structure 107 may include a plurality of individual spacer elements, which may be separated by respective liner materials (not shown) in order to provide a respective controllability of etch processes during the patterning of the spacer structure 107. In other cases, the spacer structure 107 may be reduced to a certain degree so as to reduce the width dimensions and/or the height dimensions thereof, depending on the process strategy. Consequently, unless explicitly set forth otherwise in the specification and/or the appended claims, the spacer structure 107 may have any configuration as required for the semiconductor device 100 under consideration.

Furthermore, in this manufacturing stage, a stress-inducing layer or overlayer 110 may be formed above the transistor 150, wherein, in illustrative embodiments, the stressed layer 110 may have a high tensile stress, wherein the respective intrinsic stress may be approximately 1 GPa or significantly higher, such as 2 GPa and more, depending on the device requirements. For instance, the stressed overlayer 110 may be comprised of silicon nitride, which may be directly in contact with the respective transistor areas, i.e., the drain and source regions 103 and the gate electrode 106, while, in other illustrative embodiments, an intermediate layer may be provided, as will be explained later on in more detail. Furthermore, it may be appreciated that typically respective metal silicide regions (not shown) may be provided in the drain and source regions 103 and in the gate electrode 106, in order to reduce the corresponding contact resistance for respective contact plugs to be formed in a later manufacturing stage. In this case, the stress layer 110 may be in direct contact with the respective metal silicide regions, unless respective intermediate layers may be provided, as will be discussed later on.

Furthermore, a first dielectric layer 111A of an interlayer dielectric material 111 is formed above the transistor 150, wherein, in one illustrative embodiment, the first dielectric layer 111A is formed on the stress layer 110, while, in other illustrative embodiments, an intermediate layer may be provided, if required. The first dielectric layer 111A may exhibit an intrinsic stress of the same type as the stress layer 110. That is, the stress layer 110 may act as a tensile stress source with respect to any underlying material, such as the drain and source regions 103, the sidewall spacer structure 107 and the gate electrode 106. Similarly, the first dielectric layer 111A may act as a tensile stress source for the underlying layer 110 so that, in combination, both layers 111A and 110 may act as a combined tensile stress-inducing source for the transistor 150. As previously explained, in conventional devices, a respective transistor element may typically be embedded into a PECVD silicon dioxide having a moderately high compressive stress so that the respective layer may act as a stress relaxation layer for an underlying contact etch stop layer having a high tensile stress. In the embodiment shown in FIG. 1a, the first dielectric layer 111A is enclosed by a second dielectric layer 111B, which may have a significantly increased thickness compared to the layer 111A, wherein, in one illustrative embodiment, the layer 111B may be comprised of a silicon dioxide material having the desired mechanical characteristics. That is, the layer 111B may represent a silicon dioxide material formed on the basis of a PECVD process. However, contrary to conventional devices, the layer 111A may serve as a “buffer” layer to act as a tensile stress source for the underlying stress layer 110 and provide a respective transition area for the compressive stress acting on the layer 111A due to the compressive stress of the material 111B.

The semiconductor device 100 as shown in FIG. 1a may be formed according to the following processes. After providing the substrate 101 having formed thereon the semiconductor layer 102, respective isolation structures may be formed in order to define the respective active semiconductor regions. Thereafter, an appropriate vertical dopant profile may be established, for instance as required for an N-channel transistor. Thereafter, the gate electrode 106 and the gate insulation layer 105 may be formed on the basis of sophisticated oxidation and/or deposition techniques followed by advanced photolithography processes and highly sophisticated etch techniques for patterning the gate electrode 106 and the gate insulation layer 105. Thereafter, the spacer structure 107 may be formed with dimensions as required for profiling the lateral dopant profile for the drain and source regions 103 on the basis of sophisticated ion implantation techniques and/or diffusion processes, epitaxial growth techniques and the like. For instance, the stress-inducing mechanism provided by the layers 110 and 111A may be combined with other strain-inducing sources, such as strained semiconductor material formed in or below the channel region 104 and/or in the drain and source regions 103, wherein, for instance, in some approaches, respective recesses may be formed so as to epitaxially grow an appropriate semiconductor compound for inducing the desired type of strain in the channel region 104. In this case, a certain amount of dopants may also be incorporated during the epitaxial growth process. After having incorporated the required dopant concentration, respective anneal processes may be performed at any appropriate manufacturing stage so as to activate the dopants and to re-crystallize implantation-induced lattice damage. Moreover, respective metal silicide processes may be performed if a respective reduction in resistance of the contact portions is required.

Thereafter, the stress layer 110 may be formed on the basis of plasma enhanced deposition techniques, wherein, in some illustrative embodiments, the layer 110 may be provided in the form of a silicon nitride layer having a high tensile stress. During a plasma enhanced deposition process, the finally obtained material characteristics of the material being deposited may depend significantly on the process parameters, such as pressure, substrate temperature, type of carrier gases, and in particular ion bombardment during the deposition process. Based on these process parameters, an appropriate parameter setting may be selected so as to deposit a corresponding material on the exposed surface portions with a high tensile stress. Due to the high tensile stress in the layer 110, a respective stress is exerted to the underlying materials, such as the surfaces of the drain and source regions 103, wherein a corresponding stress may result in a corresponding strain, which may finally be transferred into the channel region 104. After the formation of the overlayer 110, which in one illustrative embodiment is provided in the form of a contact etch stop layer, i.e., the material of the layer 110 may have a significantly different etch behavior compared to at least the material 111A so as to enable a reliable control of a highly anisotropic etch process to be performed at a later stage for forming respective contact openings. The layer 111A may be formed, for instance, in one illustrative embodiment, on the basis of a SACVD process on the basis of TEOS so as to obtain a silicon dioxide material having a moderately high tensile stress upon deposition. That is, the material of the layer 111A may be deposited during the SACVD process so as to exhibit a tensile stress, thereby enhancing the overall tensile effect on the drain and source regions 103. As previously explained, the SACVD process may be performed at significantly higher pressures at a temperature of approximately 400-600° C., which may still be compatible with the thermal budget of the device 150. Furthermore, the layer 111A may be formed as a substantially conformal layer, while, in other cases, the process parameters, such as pressure and temperature, may be selected so as to obtain a substantially flow-like behavior, thereby also equalizing to a certain degree the surface topography created by the gate electrode 106.

Thereafter, the remaining material of the interlayer dielectric material 111 may be provided in the form of the second dielectric layer 111B, which provides the mechanical and barrier characteristics as required for the further processing of the device 100. Thus, in one illustrative embodiment, a plasma enhanced CVD process is performed on the basis of TEOS using well-established deposition recipes, wherein, for instance, a contact of the device 100 after the formation of the layer 111A with a moisture-containing atmosphere may be substantially avoided so as to not unduly incorporate water into the layer 111A, which may cause an undue stress relaxation. For this purpose, the layers 111A and 111B may be formed in appropriately designed cluster tools, in which contact of the device 100 with moisture between the respective deposition processes may be minimized. In other cases, appropriate transport conditions may be established so as to reduce the exposure to moisture-containing gases. In other illustrative embodiments, the layer 111A may be protected by any appropriate sacrificial layer, when a further processing of the device 100 may require respective transportation activities, queue times and the like. In still other illustrative embodiments, the layer 111A may be heat treated in an appropriate atmosphere, for instance in vacuum conditions, in order to remove water prior to the deposition of the layer 111B. Thus, in this case, any stress relaxation, which may have occurred due to the incorporation of moisture into the layer 111A, may be reversed in order to establish a desired high degree of tensile stress, which may be even higher than after deposition of the layer 111A.

FIG. 1b schematically illustrates the semiconductor device 100 in a further advanced manufacturing stage. Here, respective contact openings 111C are formed in the dielectric material 111 according to device requirements. The contact openings 111C may be formed on the basis of well-established anisotropic etch techniques, wherein an appropriately designed resist mask (not shown) may be formed above the interlayer dielectric material 111 and may be used as an etch mask for forming the openings 111C, wherein, in one illustrative embodiment, the stress layer 110 may be used as an etch stop for controlling the etch process through the interlayer dielectric material 111. In this case, it should be appreciated that significantly different etch depths may have to be provided during the corresponding etch process, since, for instance, the gate electrode 106 may also be contacted, thereby requiring a reliable stop at the layer 110, while the etch front may further proceed towards the drain and source regions 103. Thereafter, the stress layer 110 may be etched on the basis of well-established recipes in order to connect to the respective contact areas of the transistor 150, such as the drain and source regions 103 and the gate electrode 106.

FIG. 1c schematically illustrates the device 100 according to yet a further illustrative embodiment, in which the stress transfer mechanism of the first dielectric layer 111A may be increased by appropriately adjusting the deposition behavior so as to reduce the deposition rate at substantially vertical surface portions compared to respective horizontal surface areas. In this case, the semiconductor device 100 may be exposed to a SACVD deposition process 119, wherein respective process parameters may be appropriately adjusted and/or a corresponding adhesion or surface mobility of the species being deposited may be reduced, for instance by providing a respective material at vertical surface portions, which may be accomplished on the basis of a preceding conformal deposition and a subsequent anisotropic etch process. Consequently, during the progress of the deposition for the material of the layer 111A, the material is being deposited on horizontal portions at a higher rate, as is for instance indicated by (a) which may schematically illustrate the layer 111A in an initial phase of the deposition process 119. Thus, a higher amount of stress material is deposited on the horizontal surface of the layer 110 compared to the vertical sidewall portions thereof so that in this case an increased amount of material having a desired “horizontal” stress component may be provided compared to the less efficient “vertical” stress component. Similarly, in a later stage of the deposition process 119, as indicated by (b), the corresponding desired horizontal portion is even further increased compared to the respective vertical component. Finally, as indicated by (c), an increased amount of “horizontal” stress material may be provided compared to the vertical component, thereby increasing the overall stress-inducing mechanism of the layer 111A. Consequently, the overall efficiency may be further enhanced, thereby also further increasing the respective strain in the channel region 104. Thereafter, the further processing of the device 100 may be continued as is described above with reference to FIG. 1b.

FIG. 1d schematically illustrates the semiconductor device 100 according to further illustrative embodiments, in which the above-described principle of a highly non-conformal deposition of a stress layer may be applied, additionally or alternatively, to the stress layer 110 in order to also enhance the “horizontal” stress component of this layer. Thus, a thickness of the layer 110 at substantially vertical sidewall portions of the spacer structure 107 may be significantly reduced compared to the respective horizontal thickness above the drain and source regions 103 or above the gate electrode 106. Thereafter, the layer 111A may be formed, for instance as a substantially conformal layer, as shown in FIG. 1b, or, in other illustrative embodiments, the non-conformal deposition technique may be used, as described above with reference to FIG. 1c. At any rate, the overall stress that may finally act on the drain and source regions 103 and therefore on the channel region 104 may be significantly increased. Thereafter, the further processing may be continued as is described above.

As a consequence, the provision of the first dielectric layer 111A in the form of a tensile stressed layer may significantly increase the overall tensile strain created in the channel region 104 compared to conventional techniques using a substantially compressive PECVD silicon dioxide. Furthermore, by appropriately designing the deposition behavior of the first dielectric layer 111A and/or the stress layer 110, the corresponding resulting overall stress may be even further enhanced, thereby improving the overall transistor performance without contributing additional process complexity.

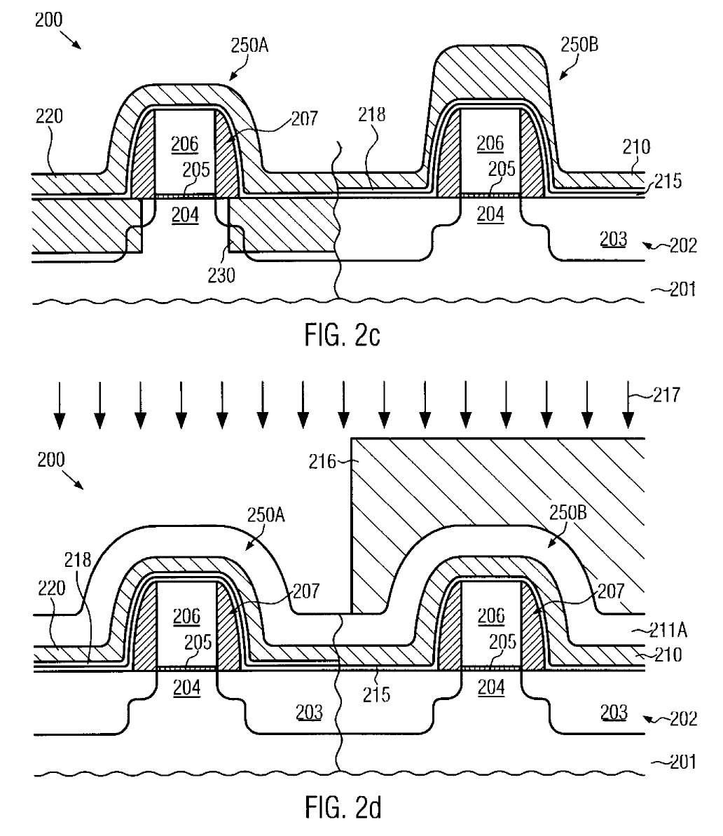

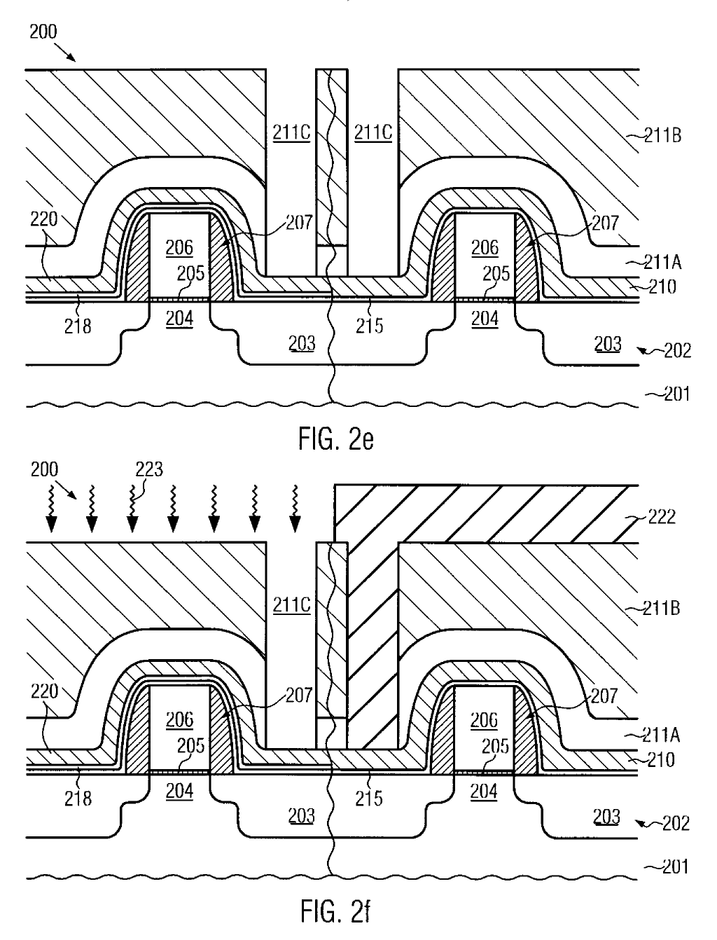

With reference to FIGS. 2a-2g, further illustrative embodiments will now be described in more detail, in which a dielectric layer having a tensile stress and being a part of the interlayer dielectric material may be provided for semiconductor devices that require different types of transistors with different stress-inducing mechanisms so as to individually increase the respective transistor performance.

FIG. 2a schematically illustrates a semiconductor device 200 comprising a first transistor 250A and a second transistor 250B, which may differ in the configuration so as to require different types of strain in the respective channel regions. For instance, the transistor 250A may represent a P-channel transistor which may require a respective compressive strain, while the transistor 250B may represent an N-channel transistor requiring a tensile strain in the respective channel region. It should be appreciated, however, that other transistor configurations may be contemplated when different types of strain may be advantageous with respect to the overall device performance. The transistors 250A, 250B may differ in their configuration with respect to dopant profiles, type of dopant used, transistor dimensions and the like. For convenience, any such differences are not shown and described herein. The semiconductor device 200 may comprise a substrate 201 having formed thereabove an appropriate semiconductor layer 202, wherein the same criteria apply for the components 201 and 202 as are previously described with reference to the device 100. Furthermore, each of the transistors 250A, 250B may comprise a gate electrode 206 formed on a respective gate insulation layer 205 separating the gate electrode 206 from a respective channel region 204. Furthermore, respective drain and source regions 203 are formed adjacent to the corresponding channel region 204. Furthermore, a sidewall spacer structure 207 may be formed on sidewalls of the respective gate electrodes 206, wherein it should be appreciated that the spacer structures 207 may be different for the respective transistor, depending on process and device requirements. With respect to the components mentioned so far, the same criteria apply as previously explained with reference to the device 100. Furthermore, one or both of the transistors 250A, 250B may comprise additional strain-inducing sources, wherein, for example, the first transistor 250A may comprise a strained semiconductor material of which a portion may be formed within the respective drain and source regions 203. For instance, the material 230 may be comprised of silicon/germanium in order to provide a respective compressive strain in the adjacent channel region 204. Furthermore, in this manufacturing stage, the device 200 may comprise a first etch stop layer 215 covering the first and second transistors 250A, 250B, wherein, in the embodiment shown, a second etch stop layer or etch indicator layer 218 may be provided in the first transistor 250A followed by a stress-inducing layer 220 having a high intrinsic stress corresponding to the requirements of the transistor 250A. For example, in the case of a P-channel transistor, the stress layer 220 may have a high intrinsic compressive stress. Similarly, the transistor 250B may comprise a stress-inducing layer 210 having a different type of intrinsic stress, such as a high tensile stress. Furthermore, in this illustrative embodiment, the tensile strain in the respective channel region 204 of the transistor 250B may have to be enhanced due to, for instance, the lack of any further strain-inducing source and thus the stress layer 210 may be provided in a highly non-conformal fashion so as to further increase the stress transfer mechanism, as previously explained.

The semiconductor device 200 as shown in FIG. 2a may be formed on the basis of the following illustrative processes. The transistors 250A, 250B may be formed substantially on the basis of the same process techniques as previously described, except for the employment of appropriate masking regimes in establishing different dopant profiles, when transistors of different conductivity type are considered. Thereafter, the etch stop layer 215 may be formed on the basis of well-established techniques, followed by the deposition of the stress layer 210 in a highly non-conformal deposition technique, as is previously explained. Thereafter, a respective etch process may be performed in order to selectively remove the layer 210 from the first transistor 250A, using the etch stop layer 215 for reliably controlling a respective etch process. Thereafter, the etch stop layer 218 or etch indicator layer 218 may be deposited on the basis of well-established recipes, followed by the deposition of the stress layer 220, which may be performed in a conventional substantially conformal manner. Thereafter, the layer 220 may be selectively removed from the transistor 250B on the basis of the layer 218, which may also be removed so as to expose the stress layer 210. Thus, in addition to an enhanced stress transfer mechanism due to the highly non-conformal layer 210, a different surface topography may be provided for the subsequent deposition of a respective tensile dielectric layer, which may, therefore, more efficiently transfer the respective stress to the underlying layer compared to the “conformal” topography of the transistor 250A, wherein an effective stress transfer to the lower-lying layer may not be desirable due to an unwanted stress relaxation. Consequently, while in the device 250B the overall stress transfer mechanism may be “amplified,” a corresponding increased influence, in this case a “negative” influence, on the layer 220 may not occur due to the “conformal” topography of the first transistor 250A.

FIG. 2b schematically illustrates the semiconductor device 200 after the deposition of the first dielectric layer 211A, which may be accomplished on the basis of the same process techniques as previously described with reference to the tensile dielectric layer 111A.

FIG. 2c schematically illustrates the device 200 in accordance with another illustrative embodiment, wherein the first and second etch stop layers 215 and 218 are provided above the transistor 250B, while the single layer 215 is provided above the transistor 250A, thereby enhancing the stress transfer mechanism in the transistor 250A so as to further reduce the negative impact of the overlying layer 211A having the tensile stress. A corresponding arrangement may be obtained by first forming the layer 220 and removing the portion thereof above the transistor 250B and thereafter forming the second etch stop layer 218 and the highly non-conformal layer 210, the portion thereof above the transistor 250A may be removed on the basis of the etch stop layer 218. Thereafter, the further processing may be continued as described in FIG. 2b. Next, a second portion of the interlayer dielectric material, such as the layer 111B as previously described, may be formed on the basis of a plasma enhanced deposition technique in order to provide the required mechanical and barrier characteristics, as previously explained.

FIG. 2d schematically illustrates the semiconductor device 200 according to still a further illustrative embodiment in which the dielectric layer 211A may be selectively modified in order to appropriately adjust the stress characteristics thereof. For instance, in the embodiment shown, the device may comprise the stress layers 220 and 210, wherein one or both layers may be provided as substantially conformal layers, as shown, or in other illustrative embodiments, one or both of these layers may be provided in a highly non-conformal configuration, as is explained above. Furthermore, the dielectric layer 211A may be formed above the transistors 250A, 250B so as to exhibit a specific amount of tensile stress, as is previously explained. Furthermore, a mask 216 may be formed, for instance a resist mask, so as to cover the transistor 250B, while exposing the transistor 250A. The mask 216 may be formed on the basis of well-established photolithography techniques. Thereafter, the device 200 may be subjected to a modification process 217 in order to selectively modify the stress characteristics of exposed portions of the layer 211A. In one illustrative embodiment, the process 217 may represent an ion implantation process so as to significantly change the crystallinity of the exposed portion of the layer 211A, thereby reducing the initially generated tensile stress. In a further illustrative embodiment, the process 217 may represent an etch process for selectively removing the exposed portion of the layer 211A, wherein the corresponding etch process may be reliably stopped by the underlying stress layer 220. For instance, highly selective wet chemical and dry etch processes are well established in the art for silicon dioxide and silicon nitride. After the process 217, the further manufacturing process may be continued by depositing a further layer of the interlayer dielectric material, as previously described, in order to appropriately passivate the transistors 250A, 250B. Consequently, a significantly enhanced stress behavior may be achieved in the transistor 250B, wherein a negative impact on the stress layer 220 in the transistor 250A may be significantly reduced or substantially completely avoided. For instance, if the further dielectric material to be deposited above the layer 211A, or the remaining portion thereof, comprises a high compressive stress, a respective performance increase may also be achieved in the first transistor 250A.

FIG. 2e schematically illustrates the semiconductor device 200 in a further advanced manufacturing stage, wherein a second dielectric layer 211B is formed on the first dielectric layer 211A and wherein respective contact openings 211C are formed within the dielectric layers 211B and 211A, wherein a respective patterning process may be reliably controlled on the basis of the first and second stress layers 220 and 210. In some illustrative embodiments, as described above with reference to FIG. 2d, the layers 211A formed above the respective transistors 250A, 250B may have different stress characteristics, due to the preceding process 217. In other illustrative embodiments, the material characteristics of the layer 211A may have not been changed up to this manufacturing stage, wherein the corresponding selective modification may be performed at a later stage.

FIG. 2f schematically illustrates the semiconductor device 200 in an advanced manufacturing stage, in which one of the transistors 250A, 250B may be covered by an appropriately formed mask layer, such as a polymer material 222, which may be provided so as to significantly reduce the effect of a modification process 223 for the transistor 250B. For example, the material 222 may be provided so as to reduce energy absorption during a laser-based or flash-based anneal process so as to maintain the respective temperature at a low level, while a moderately high device temperature may be obtained in the exposed transistor 250A. Thus, an increased temperature may also be “seen” by the respective portion of the layer 211A, which may, for instance, result in a corresponding out-diffusion of moisture, thereby increasing the respective tensile stress, which may be advantageous when the transistor 250A represents a transistor requiring a high tensile stress and the layer 220 may also be provided as a tensile stress layer. The diffusion may be enhanced by performing the treatment 223 in vacuum conditions, wherein the out-diffusion may be promoted by the corresponding non-filled contact openings 211C. Similarly, a respective species may be incorporated into the layer 211A of the transistor 250A, for instance, such as moisture or any other appropriate material, when a relaxation of the stress in the layer 211A may be desirable. Consequently, a respective adjustment of the overall stress characteristics of the layer 211A may be performed at a later stage of the manufacturing process, thereby providing enhanced flexibility for depositing the layers 210, 220, 211A, 211B, wherein, for instance, at least some of these processes may be performed as in situ processes or may be performed in dedicated cluster tools so as to enhance process throughput and production yield.

As a result, the subject matter disclosed herein provides an improved technique for the formation of transistor devices requiring stressed overlayers, wherein an enhanced efficiency of the strain-inducing mechanism for devices requiring a tensile strain may be provided by additionally forming a part of the interlayer dielectric material on the basis of silicon dioxide having a moderately high tensile stress. For this purpose, in some illustrative embodiments, a SACVD process on the basis of TEOS may be used in order to form a respective layer on a tensile stress layer, followed by the deposition of the PECVD silicon dioxide having the required mechanical and barrier characteristics. For example, for a typical N-channel transistor, a significant gain in performance of approximately 4% may be achieved by providing a respective tensile silicon dioxide layer over a tensile contact etch stop layer, compared to a conventional device comprising a standard PECVD silicon dioxide, for otherwise identical stress conditions.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first overlayer having a first type of intrinsic stress above an N-channel transistor;
forming an interlayer dielectric material on the basis of silicon dioxide on said first overlayer, said interlayer dielectric material comprising at least a layer portion having said first type of intrinsic stress; and
forming a contact opening for connecting to said N-channel transistor in said interlayer dielectric material.

2. The method of claim 1, wherein forming said interlayer dielectric material comprises forming a first dielectric layer comprised of silicon dioxide material on the basis of a sub-atmospheric chemical vapor deposition process and forming a second dielectric layer comprised of silicon dioxide on said first dielectric layer.

3. The method of claim 2, wherein said second dielectric layer is formed by a plasma enhanced chemical vapor deposition process.

4. The method of claim 3, wherein said first and second dielectric layers are formed on the basis of TEOS.

5. The method of claim 1, wherein said first overlayer has a tensile intrinsic stress of approximately 1 Giga Pascal or higher.

6. The method of claim 2, wherein said first dielectric layer is formed in a non-conformal deposition process.

7. The method of claim 1, wherein said first overlayer is formed on the basis of a non-conformal deposition process.

8. The method of claim 1, wherein said first overlayer is used as an etch stop layer when forming said contact opening.

9. The method of claim 2, further comprising forming a second overlayer above a P-channel transistor, said second overlayer having a second type of intrinsic stress other than said first type and modifying a portion of said first dielectric layer located above said P-channel transistor so as to reduce said first type of intrinsic stress.

10. The method of claim 2, further comprising forming a second overlayer above a P-channel transistor, said second overlayer having a second type of intrinsic stress other than said first type and removing a portion of said first dielectric layer located above said P-channel transistor.

11. A method, comprising:
forming a first silicon nitride layer having a tensile stress above a first transistor;
forming a first silicon dioxide layer having a tensile stress on said first silicon nitride layer; and
forming a second silicon dioxide layer on said first silicon dioxide layer.

12. The method of claim 11, further comprising forming a second silicon nitride layer above a second transistor, said second silicon nitride layer having a compressive stress.

13. The method of claim 12, wherein said first silicon nitride layer is formed by a non-conformal deposition technique.

14. The method of claim 13, wherein said first silicon dioxide layer is formed by a non-conformal deposition process.

15. The method of claim 12, further comprising selectively removing a portion of said first silicon nitride layer from above said second transistor prior to forming said second silicon nitride layer.

16. The method of claim 12, further comprising selectively modifying a portion of said first silicon dioxide layer located above said second transistor so as to reduce said tensile stress.

17. The method of claim 16, wherein said portion is selectively modified prior to forming said second silicon dioxide layer.

18. The method of claim 16, wherein said portion is selectively modified after forming contact openings in said second silicon dioxide layer.

19. A semiconductor device, comprising:
a first transistor;
a first stress layer formed above said first transistor, said first stress layer having a tensile stress;
a first dielectric layer of an interlayer dielectric material, said first dielectric layer formed on said first stress layer and having a tensile stress with respect to said first stress layer; and
a second dielectric layer of said interlayer dielectric material formed on said first dielectric layer.

20. The semiconductor device of claim 19, further comprising a second transistor and a second stress layer formed above said second transistor and having a compressive stress, said first dielectric layer having a reduced tensile stress above said second stress layer.
